(19) United States
(12) Patent Application Publication
(10) Pub. No.: US 2012/0275116 A1
(43) Pub. Date: Nov. 1, 2012

(54) HEAT RADIATING SUBSTRATE

(75) Inventor: Cheol Ho HEO, Busan-si (KR)

(73) Assignee: Samsung Electro-Mechanics Co., Ltd., Suwon (KR)

(21) Appl. No.: 13/449,486

(22) Filed: Apr. 18, 2012

(30) Foreign Application Priority Data
Apr. 28, 2011 (KR) 10-2011-0040193

(51) Int. Cl. H05K 7/20

(52) U.S. Cl. 361/720

(57) ABSTRACT

Disclosed herein is a heat radiating substrate employed in an LED package. The heat radiating substrate includes a printed circuit board made of a metal material, and having a light emitting device mounted on an upper surface thereof; a heat radiating plate provided on a lower surface of the printed circuit board to receive the heat conducted from the light emitting device to the printed circuit board and radiate the heat to the outside; and a heat radiating layer formed on a lateral surface of the printed circuit board to radiate the heat conducted to the printed circuit board to the outside through the lateral surface of the printed circuit board.

### CROSS REFERENCE(S) TO RELATED APPLICATIONS

This application claims the benefit under 35 U.S.C. Section 119 of Korean Patent Application Ser. No. 10-2011-0040193, entitled “HEAT RADIATING SUBSTRATE” filed on Apr. 28, 2011, which is hereby incorporated by reference in its entirety into this application.

### BACKGROUND OF THE INVENTION

1. Technical Field

The present invention relates to a heat radiating substrate, and more particularly to a heat radiating substrate having improved heat radiation efficiency.

2. Description of the Related Art

Recently, applications of LED are expanding to LCD TV backlights as well as, gradually expanding to illuminations.

The illumination is largely divided into indoor illumination and outdoor illumination. Particularly, in a case of the outdoor illumination, an applied current or voltage level is large, unlike the indoor illumination, and also high-power packages of 1 W class or higher, as LED packages, are generally arrayed and applied.

An LED radiates light and heat at the time of driving, in which the light accounts for about 20 to 30% and the heat about 70 to 80%, unlike a general lamp. In particular, the heat generated at the time of driving needs to be rapidly radiated to increase the light efficiency. In order to transfer this radiated heat effectively, it is general to use a light emitting device such as an LED or the like, which is packaged with a heat radiating substrate.

Hereafter, a heat radiating substrate employed in an LED package according to the related art will be described in detail as follows with reference to FIG. 1.

As shown in FIG. 1, a heat radiating substrate 1 of the related art includes a printed circuit board 10 and a heat radiating plate 20. The printed circuit board 10 is made of a metal material, particularly an aluminum (Al) material, and a light emitting device 11 such as an LED is mounted on the printed circuit board 10. The heat radiating plate 20 is provided on a lower surface of the printed circuit board 10 to radiate the heat, which is conducted from the light emitting device 11 to the printed circuit board 10, to the outside.

Here, circuit wires 12, to which the light emitting device 11 is to be electrically connected, are provided on an upper surface of the printed circuit board 10. The light emitting device 11 is electrically connected to the circuit wires 12 by a wire bonding manner or the like.

However, the heat radiating substrate 1 according to the related art constructed as above has the following problems.

The printed circuit board 10 made of a metal material, particularly an aluminum material is mainly employed as the heat radiating substrate 1 according to the related art, and here, aluminum conventionally has excellent thermal conductivity but bad heat emissivity. That is, the heat is difficult to be directly radiated through the printed circuit board 10. For this reason, the heat radiating substrate 1 according to the related art has a structure where the heat conducted from the light emitting device 11 to the printed circuit board 10 is completely radiated through the heat radiating plate 20 provided on the lower surface of the printed circuit board 10.

Since the heat radiating substrate 1 according to the related art has a heat radiating structure dependent on the heat radiating plate 20, there is a limitation in improving the heat radiation property. In order to improve the heat radiation property, the heat radiating plate 20 was forced to be upsized, but this is ineffective.

### SUMMARY OF THE INVENTION

An object of the present invention is to provide a heat radiating substrate having excellent heat radiation property and allowing miniaturization thereof as compared with the existing heat-radiating substrate having the same degree of heat radiation property, by radiating the heat, which is conducted from a light emitting device to a printed circuit board, to the outside through a heat radiating plate and directly radiating the heat generated from the light emitting device through the printed circuit board.

According to an exemplary embodiment of the present invention, there is provided a heat radiating substrate, including: a printed circuit board made of a metal material, and having a light emitting device mounted on an upper surface thereof; a heat radiating plate provided on a lower surface of the printed circuit board to receive heat conducted from the light emitting device to the printed circuit board and radiate the heat to the outside; and a heat radiating layer formed on a lateral surface of the printed circuit board to radiate the heat conducted to the printed circuit board to the outside through the lateral surface of the printed circuit board.

The heat radiating layer may include a thin film formed by coating a heat radiating coating agent on the lateral surface of the printed circuit board.

The heat radiating coating agent may include an organic-inorganic complex including a high heat-resistant modified silicon resin for improving the adhesive property with the printed circuit board, a high heat-radiant inorganic filer, and a metal filler.

An upper surface of the printed circuit board may be provided with circuit wires and the light emitting device may be electrically connected to the circuit wires.

The heat radiating plate may include a heat radiating body installed closely to the lower surface of the printed circuit board and a plurality of heat radiating pins downwardly protruded from the heat radiating body.

### BRIEF DESCRIPTION OF THE DRAWINGS

FIG. 1 is a cross-sectional view schematically showing a heat radiating substrate, which is applied to an LED package, according to the related art; and

FIG. 2 is a cross-sectional view schematically showing a heat radiating substrate according to the present invention.

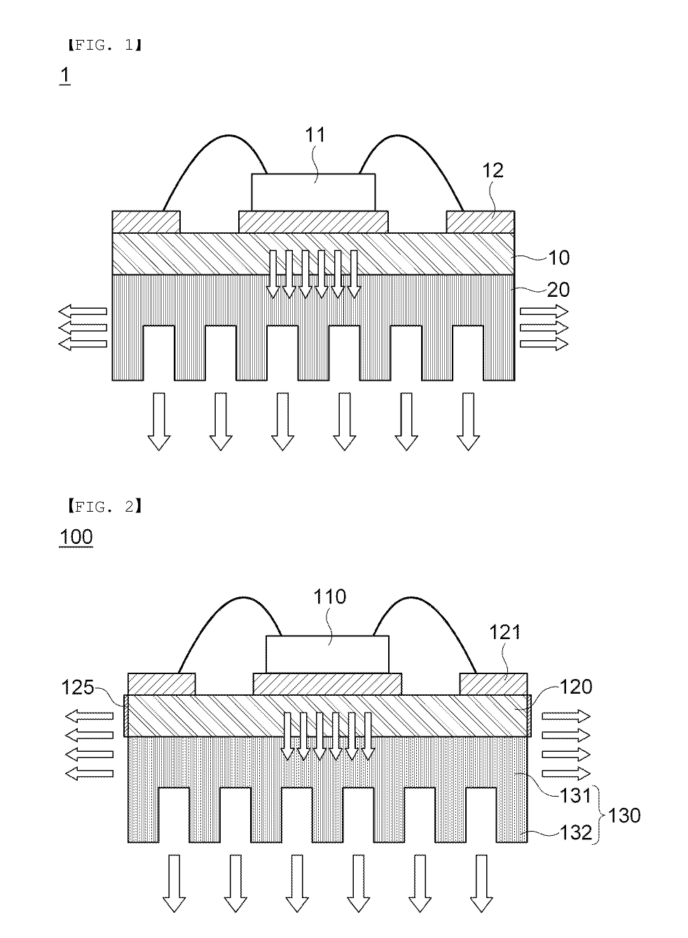

### DESCRIPTION OF THE PREFERRED EMBODIMENTS

The acting effects and technical configuration with respect to the object of a heat radiating substrate according to the present invention will be clearly understood by the following description in which exemplary embodiments of the present invention are described with reference to the accompanying drawings.

Hereafter, a heat radiating substrate according to the present invention will be described in detail with reference to the accompanying FIG. 2.

FIG. 2 is a cross-sectional view schematically showing a heat radiating substrate according to an exemplary embodiment of the present invention.

As shown in FIG. 2, a heat radiating substrate 100 according to an exemplary embodiment of the present invention includes a printed circuit board 120 on which a light emitting device 110 is mounted; a heat radiating plate 130 provided on a lower surface of the printed circuit board 120 to receive the heat, which is conducted from the light emitting device 110 to the printed circuit board 120, and radiate the heat to the outside; and a heat radiating layer 125 provided on a lateral surface of the printed circuit board 120.

Here, circuit wires 121 are formed on an upper surface of the printed circuit board 120, and the light emitting device 110 may be electrically connected to the circuit wires 121.

At this time, the light emitting device 110 may be at least one of a light emitting diode (LED) and a laser diode, and the light emitting device 110 may be electrically connected to the circuit wires 121 in a wire bonding manner.

The printed circuit board 120 may be made of a metal material, and may be particularly a conductive plate made of a conductive material having high thermal conductivity. For example, the printed circuit board 120 may be made of an aluminum (Al) material.

For this reason, the printed circuit board 120 may have an insulating film (not shown) formed on the upper surface thereof and a protecting film (not shown) formed on the lower surface thereof. Here, the insulating film may be formed by coating various kinds of resin on an upper surface of a conductive plate constituting the printed circuit board 120, and the protecting film may be an aluminum oxide film formed on a lower surface of the conductive plate constituting the printed circuit board 120.

Meanwhile, the heat radiating substrate 100 according to the present exemplary embodiment may remarkably enhance the heat radiation property, by providing the heat radiating layer 125 on the lateral surface of the printed circuit board 120.

More specifically, the heat radiating layer 125 is provided on the lateral surface of the printed circuit board 120, and thus, when the heat generated from the light emitting device 110 is conducted to the printed circuit board 120, the heat radiating layer 125 may directly radiate the heat, which is conducted to the printed circuit board 120, to the outside through the lateral surface of the printed circuit board 120.

That is, the heat radiating substrate 100 according to the present exemplary embodiment transfers the heat conducted to the printed circuit board 120 to the heat radiating plate 130. The heat radiating plate 130 radiates the heat, which is received from the printed circuit board 120 through thermal radiation, to the outside through thermal radiation and directly radiates the heat, which is conducted to the printed circuit board 120, to the outside through the lateral surface of the printed circuit board 120 by using the heat radiating layer 125, thereby maximizing the heat radiation property.

Here, the heat radiating layer 125 may be composed of a thin film, which is formed by coating a heat radiating coating agent on the lateral surface of the printed circuit board 120. The heat radiating coating agent may be preferably coated on the entire edge of the lateral surface of the printed circuit board 120, thereby radiating the heat, which is conducted to the printed circuit board 120, to the outside through the entire edge of the lateral surface of the printed circuit board 120.

The heat radiating coating agent may be composed of an organic-inorganic complex including a high heat-resistant modified silicon resin for improving the adhesive property with the printed circuit board 120, a high heat-radiant inorganic filer, and a metal filler.

For example, the high heat-resistant modified silicon resin may be composed of a modified silicon resin having high heat resistance of 200 to 300°C. The high heat-resistant modified silicon resin is used as a binder for components mixed in the organic-inorganic complex and used in order to improve the adhesive property of the heat radiating agent with the lateral surface of the printed circuit board 120.

In addition, the inorganic filler may have a composition that includes a black ceramic-based inorganic material, a high emissivity inorganic material radiating a heat energy wavelength of 0.75 to 25 μm, or a mixture thereof, and more specifically, the black ceramic-based inorganic material may include B₂O₃, BaO, ZnO, TiO, CuO, NiO, MnO₂, Cr₂O₃, Fe₂O₃, or the like. Two or more of them may be mixed and used. In addition, the metal filler may include metals, such as, alumina, silica, titanium, iron, silver, and the like, in order to enhance high heat radiation and high emissivity of the heat radiating coating agent, that is to say, the heat radiating layer 125, together with the inorganic filler. These may include two or more kinds of metal.

Meanwhile, the heat radiating plate 130 may include a heat radiating body 131 installed closely to the lower surface of the printed circuit board 120 and a plurality of heat radiating pins 132 downwardly protruded from the heat radiating body 131.

As described above, the heat radiating substrate 100 according to the present invention can maximize the heat radiation property, by indirectly radiating the heat, which is conducted to the printed circuit board 120, to the outside through the heat radiating plate 130 as well as directly radiating the heat, which is conducted to the printed circuit board 120, to the outside through the entire edge of the lateral surface of the printed circuit board 120, by using the heat radiating layer 125 having high heat radiation and high emissivity.

In addition, the present invention, when applied in a heat radiating substrate having the same level of heat radiation property as the heat radiating substrate according to the related art, allows the size of the heat radiating plate to be small by improving the heat radiation property of the heat radiating substrate 100 through the heat radiating layer 125, thereby reducing the entire size of the heat radiating substrate and allowing the miniaturization of the heat radiating substrate.

As set forth above, the heat radiating substrate according to the present invention radiates the heat, which is conducted from the light emitting device to the printed circuit board, to the outside through the heat radiating plate as well as directly radiates the heat generated from the light emitting device through the heat radiating layer provided on the lateral surface of the printed circuit board, thereby exhibiting excellent heat radiation property.

In addition, the heat radiating substrate according to the present invention has a heat radiating structure by the heat radiating layer provided on the lateral surface of the printed circuit board, other than the heat radiating plate, and thus, when having the same heat radiation property as the heat radiating substrate according to the related art, the size of the heat radiating plate can be reduced, thereby allowing the ministration thereof.

Although the exemplary embodiments of the present invention have been disclosed for illustrative purposes, those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

What is claimed is:

1. A heat radiating substrate, comprising:
a printed circuit board made of a metal material, and having a light emitting device mounted on an upper surface thereof;
a heat radiating plate provided on a lower surface of the printed circuit board to receive heat conducted from the light emitting device to the printed circuit board and radiate the heat to the outside; and
a heat radiating layer formed on a lateral surface of the printed circuit board to radiate the heat conducted to the printed circuit board to the outside through the lateral surface of the printed circuit board.

2. The heat radiating substrate according to claim 1, wherein the heat radiating layer includes a thin film formed by coating a heat radiating coating agent on the lateral surface of the printed circuit board.

3. The heat radiating substrate according to claim 2, wherein the heat radiating coating agent includes an organic-inorganic complex including a high heat-resistant modified silicon resin for improving the adhesive property with the printed circuit board, a high heat-radiant inorganic filer, and a metal filler.

4. The heat radiating substrate according to claim 1, wherein an upper surface of the printed circuit board is provided with circuit wires and the light emitting device is electrically connected to the circuit wires.

5. The heat radiating substrate according to claim 1, wherein the heat radiating plate includes a heat radiating body installed closely to the lower surface of the printed circuit board and a plurality of heat radiating pins downwardly protruded from the heat radiating body.
